(19) United States
(12) Patent Application Publication
(10) Pub. No.: US 2023/0369284 A1
(43) Pub. Date: Nov. 16, 2023

(54) CHIP ARRANGEMENT AND METHOD FOR FORMING A SINTERED CONTACT CONNECTION

(71) Applicant: PAC TECH - PACKAGING TECHNOLOGIES GMBH, Nauen (DE)

(72) Inventors: RICARDO GEELHAAR, Berlin (DE); MATTHIAS FETTKE, Berlin (DE)

(21) Appl. No.: 17/879,585

(22) Filed: Aug. 2, 2022

(30) Foreign Application Priority Data
May 12, 2022 (DE) 10 2022 111 931.9

(51) Int. Cl. H01L 23/00; H01L 23/498

(52) U.S. Cl. CPC H01L 24/85; H01L 24/48; H01L 24/45; H01L 23/49866; H01L 2224/85214; H01L 24/73; H01L 24/16; H01L 2224/73257; H01L 2224/16225; H01L 2224/85439; H01L 2224/45147; H01L 2224/48499; H01L 2224/48476; H01L 2224/48105; H01L 2924/01029; H01L 2924/01047; H01L 2224/8584; H01L 2924/40102; H01L 2924/1579; H01L 2924/15788; H01L 2924/15738; H01L 23/145

(57) ABSTRACT

A method for forming a contact connection between a chip-and a conductor material formed on a non-conductive substrate, the chip being arranged on the substrate or on another conductor material track, a sinter paste consisting of at least 40% silver or copper being applied to respective chip contact surfaces of the chip and the conductor material track, a contact conductor being immersed in the sinter paste on the chip contact surface and in the sinter paste on the conductor material track, and the contact connection being formed by sintering the sinter paste by means of laser energy.

The present application claims priority to German Patent Application No. 10 2022 111 931.9, filed May 12, 2022, which is incorporated by reference in its entirety for all purposes.

The disclosure relates to a chip arrangement and to a method for forming a contact connection between a chip, in particular a power transistor or the like, and a conductor material track, the conductor material track being formed on a non-conductive substrate and the chip being arranged on the substrate or on a conductor material track.

The chips known from the state of the art can be realized with a housing and also as a naked semiconductor component. These chips are regularly called die, bare die or bare chip. Chips of this kind are processed without a housing and are applied directly to a substrate or to a printed circuit board. In doing so, a direct contact can be formed between the chip contact surfaces of the chip and conductor material tracks. Other chip contact surfaces of the chip can be connected to other conductor material tracks via contact conductors or so-called bond wires. Contact connections of this kind are also regularly formed on power transistors. In that context, for example, a lower chip contact surface of a power transistor or chip is arranged on a conductor material track and connected to it substantially across its entire surface. An upper chip contact surface of the chip opposite of the contacted lower chip contact surface is connected to another conductor material track running next to the chip via a plurality of bond wires by ultrasonic bonding or soldering, for example. This chip arrangement ensures the availability of a sufficiently large conductor cross section for the transmission of high currents. Also, comparatively thick bond wires made of aluminum can be used for applications of this kind.

In particular in case of power transistors, such as MOSFETs, IGBTs and diodes for power modules, high thermal and electrical stresses occur, for example in a power range of 15 to 150 kW. These stresses can easily lead to component failure of the contact connection and of the chip arrangement. Moreover, the use of the chip arrangement in vehicles or wind energy plants, for example, may further reduce a service life of the chip arrangement because of high temperature fluctuations. For instance, a contact connection may break or be disconnected because of these stresses. Furthermore, a solder connection between a contact conductor and a conductor material track or a chip contact surface can only be heated to a maximum temperature of 175° C. without permanently damaging the contact connection. Furthermore, a chip arrangement of this kind is comparatively expensive to produce because a plurality of contact conductors has to be arranged between the chip contact surface and the conductor material track in order to transmit high currents.

Therefore, it is the object of the present disclosure to propose a chip arrangement having a contact connection and a method for forming a contact connection in which the contact connection has an increased service life, in particular an increased resistance to temperature fluctuations or high temperatures, and improved conductivity and is additionally easy to produce. The contact connection and the method are supposed to be cost-effective, reliable and adaptable to the connection partners. To attain the object, a method having the features of independent claim 1 is proposed. Furthermore, a chip arrangement having the features of independent claim 12 is proposed.

Advantageous embodiments of the disclosure are the subject matter of the dependent claims. Moreover, any and all combinations of at least two features disclosed in the description, the claims, and/or the figures fall within the scope of the disclosure. Naturally, the explanations given in connection with the method equivalently relate to the chip arrangement according to the disclosure and vice-versa, albeit not verbatim. In particular, linguistically common rephrasing and/or an analogous replacement of respective terms within the scope of common linguistic practice, in particular the use of synonyms backed by the generally recognized linguistic literature, are of course comprised by the content of the disclosure at hand without every variation having to be expressly mentioned.

In the method according to the disclosure for forming a contact connection between a chip, in particular a power transistor or the like, and a conductor material track, the conductor material track is formed on a non-conductive substrate, the chip being arranged on the substrate or on another conductor material track. To form a contact connection between the chip and the conductor material track, a sinter paste having silver or copper is applied to respective contact surfaces of the chip and the conductor material track, and a contact conductor is immersed in the sinter paste on the chip contact surface and in the sinter paste on the conductor material track. The sinter paste can be applied by screen printing, stencil printing or direct dispensing. The solvent contained in the sinter paste is at least partially vaporized by heating and the contact connection is formed by sintering the sinter paste by means of laser energy. In the context of the disclosure, it has been found that the contact connection is particularly durable and easy to produce if the sinter paste has a silver or copper content of at least 40%. It has proven advantageous for the sinter paste to have a silver or copper content of no more than 90% so that the sinter paste can be handled and applied in a reliable and precisely reproducible manner.

The substrate can be made of a plastic material or a ceramic material, conductor material tracks for connecting electronic components or semiconductor components being formed on the substrate at first. This may take place by way of a method well understood in the state of the art. It has proven advantageous for the substrate to be made of silicon or glass or a thermoplastic material, preferably polyethylene naphthalate, in particular in terms of simple processing.

The chip can subsequently be arranged either directly on the non-conductive substrate or on a conductor material track, a distinction having to be made between the conductor material track on which the chip is arranged and the conductor material track to which the chip is to be connected. If the chip is arranged on a conductor material track, it will be electrically connected to the latter. On an upper side of the chip facing away from the substrate and/or the conductor material track, at least one upper chip contact surface is formed for forming a contact with the chip. By forming the contact connection, the chip contact surface will be connected to a conductor material track adjacent relative to the chip and/or to another conductor material track via a contact conductor. To this end, a liquid or pasty sinter paste consisting of at least 40% silver or copper is applied to the conductor material track to be connected to the chip. The sinter paste is also applied to the upper chip contact surface. The sinter paste can be applied automatically or by means of an applicator.

After the application of the sinter paste, the contact conductor is immersed in the sinter paste on the chip contact surface and in the sinter paste on the conductor material track so that the contact conductor is at least partially surrounded by the sinter paste in each case. In the context of the disclosure, it has been found that the durability of the contact connection can be increased as a function of the wetting of the free ends of the contact conductor with sinter paste. Hence, the contact conductor is preferably immersed in the sinter paste in such a manner that the sinter paste encloses the immersed section of the contact conductor.

In addition to the silver or copper content of at least 40%, the sinter paste contains a carrier which has a solvent, the solvent being at least partially vaporized by heating, which may lead to a reduction of the volume of the applied sinter paste. In the context of the disclosure, a carrier refers to a liquid or pasty substance which can be blended with silver or copper particles. Hence, in the context of the disclosure, the sinter paste can be present in liquid form, in which case the sinter paste could also be referred to as ink, or in pasty form as a function of the carrier. Depending on the extent of heating, the solvent present in the carrier can be vaporized by evaporation or boiling. Preferably, the solvent is at least partially vaporized after the immersion of a contact conductor in the sinter paste on the chip contact surface and/or in the sinter paste on the conductor material track and prior to the sintering by means of laser energy.

The ultimate formation of the contact connection between the conductor material track and the chip via the contact conductor takes place by sintering of the sinter paste by means of laser energy, a laser beam being aimed directly or indirectly at an area of the contact connection. The use of an NIR laser (near infrared laser), which preferably operates in a wavelength range of 780 nm to 1400 nm, has proven particularly simple in terms of handling and effective in terms of the introduction of energy into the sinter paste in the context of the u. Silver particles or copper particles contained in the sinter paste will at least partially melt or sinter together, thus forming an electrical and mechanical connection between the chip contact surface and the conductor material track via the contact conductor. The application of the sinter paste to the chip contact surface, the conductor material track and, if applicable, the contact conductor and the subsequent sintering can take place in parallel or in sequence, wherein it is immaterial then whether the chip contact surface or the conductor material track is the first to be provided with sinter paste. So it is possible to first provide the chip contact surface and the conductor material track with sinter paste, to subsequently immerse the contact conductor in the sinter paste on the chip contact surface and in the sinter paste on the conductor material track, and to subsequently sinter the sinter paste on the chip contact surface and on the conductor material track to fully form the contact connection. On the other hand, it is also possible, for example, to fully form a contact on the chip contact surface first and on the conductor material track second, i.e., apply sinter paste, immerse the contact conductor, vaporize the solvent, and sinter the sinter paste by means of laser energy, and only then form the second contact in the same manner on the conductor material track, for example.

Regarding the order of the method steps, the contact conductor can either be arranged on the chip contact surface or the conductor material track first and the sinter paste can be applied second, in which case the sinter paste is applied to the chip contact surface or the conductor material track with the contact conductor in such a manner that the latter is at least partially enclosed by the sinter paste. However, it has proven advantageous if the sinter paste is applied to the chip contact surface and/or the conductor material track first and the contact conductor is arranged on the chip contact surface and/or the conductor material track second in such a manner that the contact conductor is immersed in the previously applied sinter paste, preferably in such a manner that an end of the contact conductor is fully immersed. In this way, it can be ensured in a simple manner that the contact conductor will be at least partially, but preferably fully, enclosed by the sinter paste, which, in turn, significantly increases the durability of the contact connection. Since a sinter paste having a silver or copper content of at least 40% is used instead of a solder for producing the contact connection, the contact connection has a significantly extended service life. Moreover, the sintered paste is substantially more resistant to high temperature fluctuations and high operating temperatures. For instance, operating temperatures of the chip of up to 300° C. can be achieved with sintered sinter paste containing at least 40% silver.

The method according to the disclosure offers other advantages in terms of minimizing the risk of fracture of the contact conductor, the flexible design of the loop shape of the contact conductor, and the homogenous heat distribution during the current carrying capacity test of the chip arrangement produced with the method according to the disclosure. Moreover, there is no mechanical strain on the chip during the formation of a contact connection by means of the method according to the disclosure.

Moreover, it is no longer necessary to form a large number of contact connections between the chip terminal surface and the conductor material track in order to be able to transmit high currents. Moreover, contact conductors having a relatively large cross section can be used since the method according to the disclosure can be implemented largely independently from a cross section of the contact conductor, making it possible to substantially reduce the number of contact conductors and, thus, contact connections for transmitting currents according to specification. This makes the implementation of the chip arrangement and the method for producing the chip arrangement cost-effective.

The advantages of the introduction of energy by means of laser for sintering the sinter paste compared to direct thermal heating in an oven, for example, are the high selectivity, a simple and reproducible time control, and a short process time in the range of seconds or milliseconds. This is in contrast to generic sintering in infrared or convection ovens, where the sintering process typically takes several minutes. The use of the laser additionally minimizes the thermal strain on the connection partners and the substrate, which means that it is also possible for thermally sensitive components to be used without damaging them by temperature exposure. There is almost no thermal strain on the components since the sintering site can be heated in very little time and in a highly localized manner. Leaching of the conductor tracks can also be advantageously avoided in this way.

Furthermore, sintering by means of laser energy offers the advantage over other types of sintering, for example, in a sintering oven, that energy can be introduced very specifically and thus specification-dependent contact connections can also be produced; in particular, the structure of the sinter paste can be specifically adjusted. Thus, highly densified zones having barely any air pockets can be formed in the sinter paste by sintering by means of laser energy as a function of the requirements placed on the contact connection. This allows in particular the surface of the sintered sinter paste to be highly durable chemically and mechanically, which not only makes the contact connection more stable but also allows the connection partners, namely the contact conductor, the conductor material track, and the chip contact surface, to be protected.

A sinter paste having silver or copper nanoparticles can be used as the sinter paste. Silver or copper nanoparticles allow a simple and homogenous distribution of the particles in the sinter paste, the selection of the particle sizes and the content of the silver or copper nanoparticles in the sinter paste allowing the sintering reaction to be controlled and advantageously adapted to the problems posed by the components to be connected, which is of particular advantage when temperature-sensitive components are used. Furthermore, the use of silver or copper nanoparticles in the sinter paste allows the necessary sintering temperature to be lowered and a high conductivity to be achieved. The person skilled in the art knows that nanoparticles typically have a particle size of 1 nm to 100 nm. Preferably, a sinter paste having a content of silver or copper nanoparticles between 50% and 60% is used. Particularly preferably, a sinter paste having a content of silver nanoparticles between 50% and 60% is used. Most preferably, a sinter paste containing silver nanoparticles is used, the content of silver nanoparticles in the sinter paste being 55%.

In the context of the disclosure, it has proven advantageous for a sinter paste comprising an alcohol solution, a glycol solution or epoxy resin as a carrier to be used as the sinter paste, the silver or the copper being dissolved in the carrier, or the carrier serving as a matrix material for the silver or the copper of the sinter paste. A sinter paste comprising an alcohol solution, a glycol solution or epoxy resin can be processed particularly easily. Furthermore, the use of a sinter paste comprising an alcohol-glycol solution or an epoxy resin has proven particularly advantageous with regard to the vaporization of the solvent contained in the carrier and thus in the sinter paste by heating. Preferably, a sinter paste comprising an alcohol solution or a glycol solution and consisting of at least 50% silver is used. When using an alcohol solution or a glycol solution as the carrier, the alcohol or the glycol is preferably the vaporizable solvent. Alternatively, a sinter paste which comprises epoxy resin as a carrier comprising a vaporizable solvent and which consists of at least 80%, preferably 88%, silver is used. With the mentioned paste compositions, the best results regarding durability and conductivity could be achieved.

Furthermore, in the context of the disclosure, it has been found that the layer thickness of the sinter paste can have an impact on the durability of the contact connection. Hence, the layer thickness of the sinter paste may be adapted both to the requirements of the contact connection and to the design of the contact conductor. Preferably, the sinter paste is applied with a layer thickness of 100 μm to 700 μm. Further preferably, the sinter paste is applied with a layer thickness of 80 to 120 μm, preferably 100 μm if a wire or a stranded wire having a diameter of 15 to 50 μm, preferably with a diameter of 30 μm is used as the contact conductor. If a flat wire preferably having a width between 200 and 400 μm is used as the contact conductor, the sinter paste is applied with a layer thickness of 500 to 700 μm. By selecting the suitable layer thickness as a function of the design of the contact conductor, it can be ensured that the contact conductor can be immersed in the sinter paste sufficiently, i.e., the contact conductor can be covered or enclosed by the sinter paste.

A stranded wire or a wire or a flat wire can be used as a contact conductor. Preferably, a stranded wire or a wire or a flat wire made of gold or a gold alloy or copper or a copper alloy or silver or a silver alloy is used in order to achieve as high a conductivity as possible and a good connection to the chip contact surface, the conductor material track, and the sinter paste. Preferably, a stranded wire is used as the contact conductor since it is particularly flexible and therefore, contrary to a use of a solid wire, no shear or tensile stresses such as those potentially caused by large temperature differences can occur in the respective contacts on the chip contact surface or the conductor material track. Even more preferably, a flat litz wire is used since it has a relatively large cross section compared to a wire or a bond wire, which is why it is able to transmit high currents. Furthermore, it has been found advantageous for the design of the contact conductor to be adapted to the design of the sinter paste in order to ensure as stable a connection as possible and as high a conductivity as possible. In other words, this means that a contact conductor made of silver or a silver alloy is preferably used if the sinter paste comprises silver, and that a contact conductor made of copper or a copper alloy is preferably used if the sinter paste comprises copper.

When a stranded wire or a flat litz wire is used as a contact conductor, the stranded wire or the flat litz wire can be at least partially infiltrated by the sinter paste. By immersing the stranded wire or the flat litz wire in the sinter paste, the sinter paste and thus the silver particles or copper particles present in the sinter paste can penetrate the stranded wire or the flat litz wire so that a particularly tight connection between the sinter paste and the contact conductor can be formed during sintering. Advantageously, the sinter paste can additionally be absorbed by the stranded wire or the flat litz wire in a simple manner without further methods steps owing to the capillary effect of the stranded wire or the flat litz wire so that the contact conductor is filled with silver particles or copper particles in the area of the chip contact surface or of the conductor material track. Furthermore, it may be envisaged that only one contact conductor, preferably one stranded wire or one wire or one flat wire, is used per chip contact surface. This is made possible by the fact that the contact conductor can have a comparatively large width that is approximated to the dimensions of the chip contact surface. In this case, it will no longer be necessary to use a plurality of contact conductors. If only one contact conductor is used for connecting the chip contact surface and the conductor material track, the method can be implemented in a particularly quick and thus cost-effective manner.

It has proven advantageous for laser energy of 10 mJ to 40 mJ to be applied for sintering the sinter paste by means of laser energy. Preferably, energy of 15 mJ to 30 mJ is introduced. Particularly good results in terms of the durability of the contact connection could be achieved if laser energy of 19 mJ to 24 mJ is applied for sintering the sinter paste by means of laser energy. Most preferably, laser energy of 19 mJ, 19.5 mJ, 20 mJ, 20.5 mJ or 21 mJ is applied for sintering the sinter paste by means of laser energy if a sinter paste composed of at least 50% silver and an alcohol-glycol solution as a solvent is used. If a sinter paste comprising epoxy resin and at least 80% silver is used, it has proven advantageous for laser energy of 21 mJ, 21.5 mJ, 22 mJ, 22.5 mJ or 23 mJ to be applied for sintering such a sinter paste by means of laser energy so as to increase the mechanical stability and to achieve a shear strength between 300 gf and 350 gf (Gram force).

Furthermore, it has proven advantageous for a pulse laser to be used to apply the laser energy, the pulse laser being operated with a pulse duration in the range of 1 ms to 4 ms for sintering the sinter paste by means of laser energy. Preferably, the laser is operated with a pulse duration of 2.1 ms, 2.2 ms, 2.3 ms, 2.4 ms, 2.5 ms, 2.6 ms, 2.7 ms, 2.8 ms, 2.9 ms or 3 ms. Particularly preferably, the laser is operated with a pulse duration of 2.3 ms for sintering the sinter paste by means of laser energy.

It is possible for the solvent contained in the sinter paste to be at least partially vaporized by heating in an oven, preferably prior to the sintering of the sinter paste. Vaporization in an oven offers the simple and effective option of heating multiple contact connections simultaneously and at least partially vaporizing the solvent contained in the sinter paste used for forming the contact connection. The at least partial vaporization of the solvent by heating preferably takes place in a convection oven.

It has proven advantageous for the solvent contained in the sinter paste to be at least partially vaporized in an oven at a temperature in the range of 60° C. to 250° C. The heat treatment of a material is also known to the person skilled in the art as “tempering”. Preferably, the tempering for the at least partial vaporization of the solvent contained in the sinter paste in an oven takes place for a duration of 3 minutes to 10 minutes, particularly preferably for a duration of 5 minutes. Further preferably, the heating of the connection partners and in particular of the sinter paste for the at least partial vaporization of the solvent contained in the sinter paste in an oven takes place at a temperature between 80° C. and 230° C. In the context of the disclosure, it has been found that an efficient vaporization and a particularly stable and reliable connection can be achieved using an alcohol-glycol solution and a sinter paste comprising at least 50% silver if the solvent is at least partially vaporized in an oven at a temperature of 150° C., 160° C., 170° C., 180° C., 190° C., 200° C., 210° C., 220° C. When a sinter paste comprising an epoxy resin and at least 80% silver is used, the solvent contained in the sinter paste is vaporized in an oven at a temperature preferably between 180° C. and 230° C. Further preferably, when a sinter paste comprising an epoxy resin and at least 80% silver is used, a substrate made of glass or silicon, which is referred to as a wafer, can be used, the solvent contained in the sinter paste being vaporized in an oven at a temperature of 170° C., 180° C. or 190° C. if a wafer is used, and the solvent contained in the sinter paste being vaporized in an oven at a temperature of 220° C., 230° C. or 240° C., particularly preferably at 230° C., if a glass substrate is used. By adhering to the mentioned temperature ranges as a function of the sinter paste and the substrate used, a contact connection which is particularly durable and simple to produce can be obtained.

Alternatively or additionally to tempering in an oven, the sinter paste can be heated by arranging the substrate on or on top of a heating element. The substrate and thus the conductor material track and the chip contact surface can be heated by the heating element until the solvent of the sinter paste vaporizes. Preferably, the sinter paste is heated to the temperatures described above in connection with the heating in an oven. Thus, the use of an oven or of a similar device for external heating of the sinter paste can be entirely omitted.

Moreover, it may be envisaged that the substrate is supported by means of a clamping means during heating. On the one hand, the substrate can thus be exactly positioned, and on the other hand, the clamping means can have a heating element or form the heating element itself. In this way, heating of the sinter paste to vaporize the solvent is simplified even further and a targeted introduction of energy is made possible.

In the course of the method, the sinter paste can be sintered prior to a complete vaporization of the solvent. Thus, the sinter paste can be prevented from fully drying before it is sintered, which would be considered disadvantageous. Completely solvent-free or dried sinter paste is prone to fractures due to the drying process or due to movement, which may be conducive to failure of the contact connection.

The contact conductor can be fixed on the chip contact surface and/or the conductor material track during sintering by means of laser energy using a fixing device. It is possible for the contact conductor to be pressed onto the chip contact surface and/or onto the conductor material track during sintering. Preferably, however, the contact conductor is merely fixed on the chip contact surface and/or the terminal surface of the conductor material track without pressure, i.e., without pressure being exerted on the contact conductor in the area of connection between the contact conductor and the chip contact surface or the contact conductor and the conductor material track, so as to avoid damage to the contact conductor and the chip contact surface or the conductor material track. In this way, a particularly tight connection between the contact conductor and the chip contact surface or the conductor material track can be formed without one of the connection partners being damaged. Furthermore, a formation of undesired cracks during cooling of the sintered sinter paste can be avoided, in particular if the fixation of the contact conductor by the fixing device is maintained for the duration of the cooling process.

According to an embodiment of the method, the contact conductor is fed from a contact conductor supply and the section of the contact conductor connecting the chip to the conductor material track is severed from the contact conductor supply after sintering by means of laser energy. For example, the contact conductor can be fed to the chip contact surface or to the conductor material track from a contact conductor supply, which is a coil or a reel. Preferably, the contact conductor is fed from the contact conductor supply in an automated manner. First, an end of the contact conductor can be placed on the chip contact surface, and then a section of the contact conductor can be placed on the conductor material track or vice-versa. After sintering of the sinter paste and formation of the contact connection, the contact conductor can be severed in such a manner that the section forming the contact connection for connecting the chip and the conductor material track remains and an end of the contact conductor which has become a free end because of the severing is available again for forming another contact connection. This free end of the contact conductor fed from a contact conductor supply can subsequently be moved toward another chip contact surface or another conductor material track for forming another contact connection, which means that a particularly effective processing of the contact conductor is ensured, in particular when multiple contact connections are formed. Moreover, severing the contact conductor from a contact material supply saves material and shortens the process at the contact conductor since the contact conductor can be severed at the correct length for each contact connection instead of having to provide such contact conductor sections in advance which have to be shortened after forming the contact connection, which would produce waste.

The chip contact surface can be formed by applying a copper strip to a chip surface. In that case, the chip surface can be made of a semiconductor material, such as silicon. By applying the copper strip, metallization of the chip surface is particularly simple. The copper strip can also achieve a formation of the electrical contact with the contact conductor.

Moreover or alternatively, a contact metallization can be applied to the conductor material track and/or to the chip contact surface and/or the sinter paste, in particular the sintered sinter paste. The contact metallization can be comparatively thin and substantially improve wettability of the chip contact surface and of the conductor material track with sinter paste. The contact metallization is preferably applied with a layer thickness of 2 μm to 4 μm. Particularly preferably, the layer thickness of the contact metallization is 3 μm, 3.1 μm, 3.2 μm, 3.3 μm, or 3.4 μm. Most preferably, the contact metallization has a layer thickness of 3.2 μm. Applying a contact metallization leads to improved wettability and an increase in reproducibility and a protection against thermal conditions.

The contact metallization can be formed by physical vapor deposition (PVD), sputter deposition, galvanization or electroless plating. Preferably, the contact metallization is formed by electrolytic deposition. The contact metallization can be made of silver, nickel, copper, gold, palladium, aluminum or another alloy of one of said metals. Preferably, a contact metallization made of silver or copper is formed, which can advantageously be produced comparatively thin and also allows a comparatively better current density distribution and a particularly favorable thermal dissipation of heat energy, such as for cooling the chip. It has been found that when a sinter paste containing silver is used, the contact metallization is advantageously made from silver so that as good a connection as possible of the silver of the sinter paste with the silver of the contact metallization during sintering is made possible. Correspondingly, it has proven advantageous for the contact metallization to be made from copper when a sinter paste comprising copper is used.

The chip arrangement according to the disclosure, in particular for power transistors or the like, comprises a chip, a non-conductive substrate having a conductor material track formed thereon and a contact conductor, the chip having been arranged on the substrate or on a conductor material track, wherein a sinter paste consisting of at least 40% silver or copper has been applied to respective chip contact surfaces of the chip and the conductor material track, the contact conductor having been immersed in the sinter paste on the chip contact surface and in the sinter paste on the conductor material track, a solvent contained in the sinter paste having been vaporized by heating, and a contact connection having been formed by sintering of the sinter paste by means of laser energy. The sintered contact connection is significantly more resistant and durable than a contact connection which is configured in the manner of a generic solder connection. In particular the resistance to temperature conditions and temperature fluctuations is significantly increased. Furthermore, sintering the sinter paste by means of laser energy also affects the chip arrangement and the contact connection in that the targeted introduction of energy by means of laser allows highly densified zones to be formed at the surface of the sinter paste. These zones have barely any air pockets or residual solvent, which is why they are particularly resistant. On the other hand, sintering in an oven, for example, will produce a homogenous and porous sinter paste layer which has more air pockets and a lower durability by comparison.

Regarding other advantageous effects of the chip arrangement according to the disclosure, reference is made to the description of advantages of the method according to the disclosure. Other advantageous embodiments of the chip arrangement additionally become apparent from the dependent claims back-referenced to claim 1 and claim 12.

It has proven advantageous for the substrate to be made of silicon or glass or a thermoplastic material, preferably polyethylene naphthalate. A substrate made of glass preferably has a thickness of 0.8 mm, 0.9 mm, 1 mm, 1.1 mm or 1.2 mm. A substrate made of a thermoplastic material, preferably polyethylene naphthalate, preferably has a layer thickness of 35 μm, 40 μm, 45 μm, 50 μm, 55 μm, 60 μm or 65 μm, a layer thickness of 50 μm being particularly preferred.

The sinter paste can comprise silver or copper nanoparticles to achieve an improved durability while maintaining a high conductivity. Advantageously, the silver or copper nanoparticles can be homogenously dispersed in the sinter paste material in a simple manner, which allows material stress in the event of temperature fluctuations, for example, to be avoided.

The contact conductor of the chip arrangement can be a stranded wire or a wire or a flat wire. Preferably, the contact conductor is a flat litz wire. Further preferably, the contact conductor is a stranded wire or a wire or a flat wire made of gold or a gold alloy or copper or a copper alloy or silver or a silver alloy. In particular if the contact conductor is a stranded wire or a flat wire, the contact connection can be formed via no more than a single a single contact conductor, and other contact conductors are unnecessary if the flat wire or the stranded wire is dimensioned sufficiently. This minimizes not only the expenditures for production and material provision but also the room for mistakes.

It has proven advantageous for the contact conductor to have a width between 10 μm and 350 μm. Preferably, a contact conductor realized as a flat wire has a width of 250 μm, 260 μm, 270 μm, 280 μm, 290 μm, 300 μm, 310 μm or 320 μm. Particularly preferably, a contact conductor realized as a flat wire has a width of 280 μm. Furthermore, a contact conductor realized as a flat wire has a preferred thickness of 25 μm, 30 μm, 35 μm, 40 μm, 45 μm, 50 μm or 55 μm. Particularly preferably, a contact conductor realized as a flat wire has a thickness of 40 μm. A contact conductor realized as a wire preferably has a thickness of 15 μm, 20 μm, 25 μm, 30 μm, 35 μm, 40 μm or 45 μm. More preferably, a contact conductor realized as a wire has a thickness of 30 μm.

To further improve the durability of the contact connection, in particular the connection between the contact conductor and the chip or between the contact conductor and the conductor material track and to ensure a conductivity according to specifications, it has proven advantageous for the sinter paste to cover the section of the contact conductor immersed in the sinter paste, in particular an end of the contact conductor. Preferably, the sinter paste fully encloses the section of the contact conductor immersed in the sinter paste. This requires that on the one hand the sinter paste is applied to the chip contact surface and the conductor material track with a sufficient layer thickness and that on the other hand a sufficient layer thickness of the sinter paste remains after sintering for covering the contact conductor so that the contact conductor stays covered, preferably fully enclosed. In the context of the disclosure, it has been found that a layer thickness of 10 μm to 700 μm remaining on the chip contact surface after sintering is advantageous. Preferably, the sinter paste on the chip contact surface has a layer thickness of 80 μm, 90 μm, 100 μm, 110 μm or 120 μm after the application of the contact conductor and the sintering if the contact conductor is a wire or a stranded wire. If the contact conductor is a flat wire, the sinter paste on the chip contact surface has a layer thickness of preferably 600 μm, 650 μm, 700 μm, 750 μm or 800 μm after the application of the contact conductor and the sintering. Further preferably, a sinter paste layer of 5°μm to 30 μm covering the contact conductor remains after sintering. Most preferably, the sinter paste on the chip contact surface has a layer thickness of 100 μm after the application of the contact conductor and the sintering if the contact conductor is a wire or a stranded wire, and a layer thickness of 700 μm if the contact conductor is a flat wire. Prior to sintering, the sinter paste is preferably applied with a layer thickness of 10 μm to 100 μm.

Of course, the embodiments and the illustrative examples mentioned above and to be explained below can be realized not only individually but also in any combination with each other without leaving the scope of the present disclosure. Also, the embodiments and the illustrative examples mentioned above and to be explained below of course equivalently or at least similarly relate to the method according to the disclosure without having to be mentioned separately for it.

Embodiments of the disclosure are schematically illustrated in the drawings and will be explained as examples below.

In the drawing:

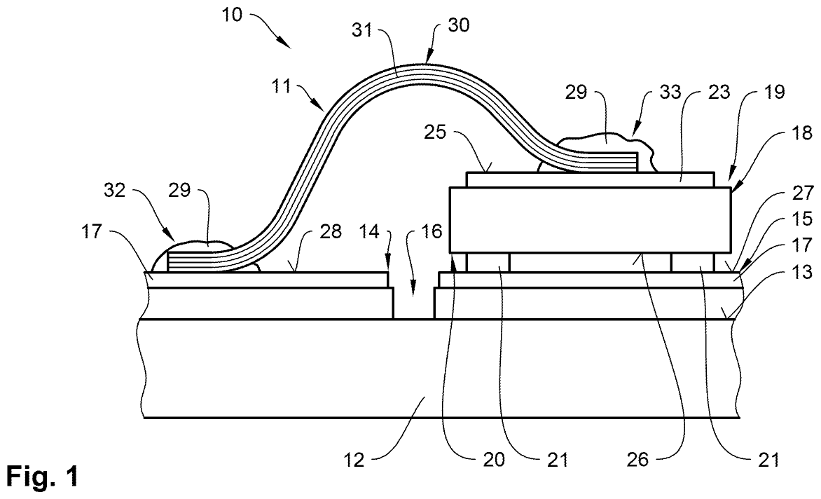

FIG. 1 shows a schematic sectional view of a first embodiment of a chip arrangement during a method step;

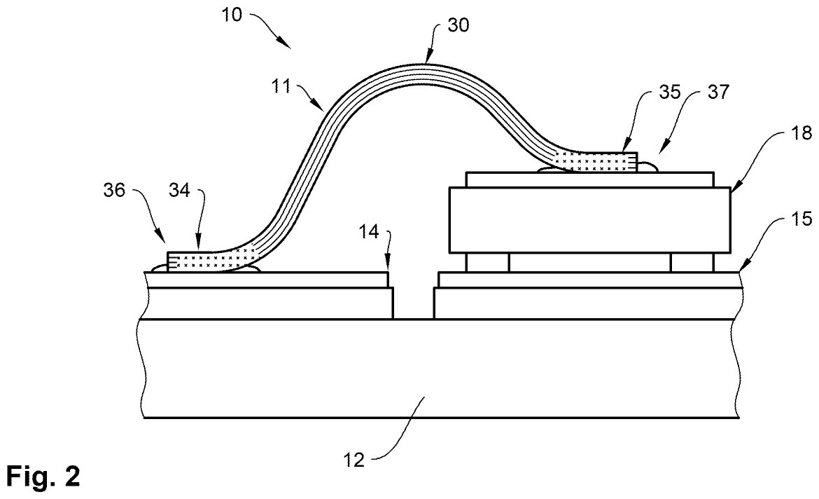

FIG. 2 shows a schematic sectional view of the chip arrangement of FIG. 1 after completion of a contact connection;

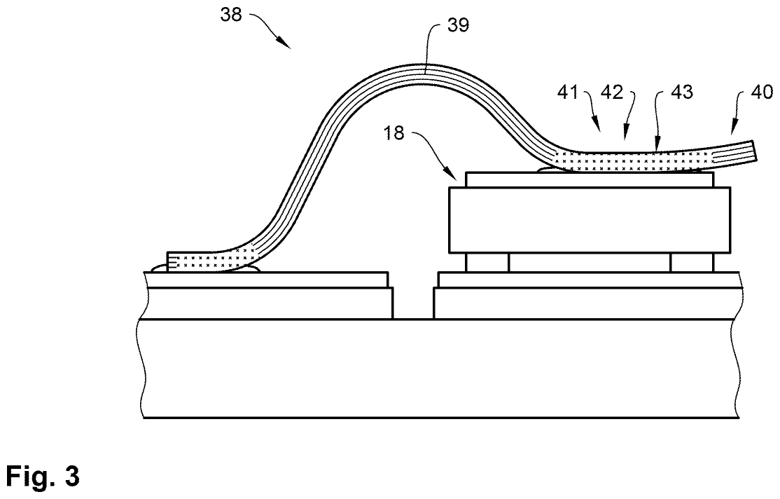

FIG. 3 shows a schematic sectional view of a second embodiment of a chip arrangement; and

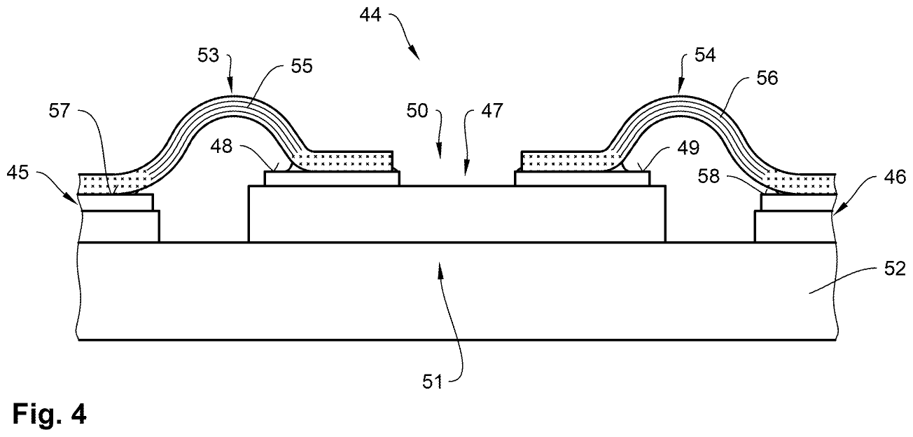

FIG. 4 shows a schematic sectional view of a third embodiment of a chip arrangement.

FIG. 1 shows a chip arrangement 10 in a schematic sectional view during the production of a contact connection 11. Chip arrangement 10 comprises a non-conductive substrate 12, on whose surface 13 a plurality of different conductor material tracks 14 and 15 are formed. Conductor material tracks 14 and 15 are separated from each other via an isolating gap 16 and are thus electrically isolated from each other. A contact metallization 17 made of silver or a silver alloy is formed on or applied to each of conductor material tracks 14 and 15. Alternatively, contact metallization 17 can also be made of nickel, copper, gold, palladium, aluminum or another alloy of one of said metals. A chip 18, which is made of a semiconductor material, is formed on conductor material track 15. A contact metallization 23 made of silver or a silver alloy is applied to a rear side 19 of chip 18 facing away from conductor material track 15, and contact bumps 21 are applied to a front side 20 of chip 18 facing toward conductor material track 15. Contact bumps 21 connect chip 18 to conductor material track 15. Accordingly, a rear chip contact surface 25 and a front chip contact surface 26 are formed on chip 18. Chip contact surface 26 of chip 18 is contacted, that is electrically connected, with a conductor surface 27 of conductor material track 15. A defined amount of sinter paste 29 has been applied to each of a conductor surface 28 of conductor material track 14 and to chip contact surface 25 of chip 18. A contact conductor 30 is realized as a flat litz wire 31 made of copper and is immersed in sinter paste 29 with each of its ends 32 and 33, sinter paste 29 substantially surrounding ends 32 and 33.

As can be taken from FIG. 2, sinter paste 29 was sintered after the solvent contained therein had largely vaporized. Sintering took place in that laser energy was introduced to sinter paste 29 and to each of ends 32 and 33. In this way, a first contact 34 of contact connection 11 was formed with sinter paste 29 and end 32 on conductor surface 28 and a second contact 35 of contact connection 11 was formed with sinter paste 29 and end 33 on chip contact surface 25. The metallic particles (not visible) of sinter paste 29 penetrated ends 32 and 33 and were sintered or partially melted together by the sintering, a particularly tight connection having been formed with filaments (not visible) of flat litz wire 31 and conductor surface 28 and chip contact surface 25, respectively. Thus, the sintered sinter paste 29 is solidified in contact areas 36 and 37.

FIG. 3 shows a second embodiment of a chip arrangement 38, which differs from the chip arrangement shown in FIG. 2 in that it comprises a flat litz wire 39 that was severed only after sintering of sinter paste 29. An end 40 of flat litz wire 39 thus protrudes from a contact area 41, a section 42 of flat litz wire 39 serving to form a contact 43 with chip 18.

FIG. 4 shows a third embodiment of a chip arrangement 44, which differs from the chip arrangement shown in FIG. 2 in that it comprises conductor material tracks 45 and 46, between which a chip 47 is arranged. Chip 47 forms two front chip contact surfaces 48 and 49 on a front side 50 of chip 47, a rear side 51 of chip 47 being arranged directly on a substrate 52. Each of chip contact surfaces 48 and 49 is connected to conductor surfaces 57 and 58 of conductor material tracks 45 and 46, respectively, via contact conductors 53 and 54, which are realized as flat litz wires 55 and 56, respectively.

1. A method for forming a contact connection between a chip and a conductor material track, the conductor material track being formed on a non-conductive substrate, the chip being arranged on the substrate or on another conductor material track,
wherein
a sinter paste consisting of at least 40% silver or copper is applied to respective chip contact surfaces of the chip and the conductor material track, a contact conductor being immersed in the sinter paste on the chip contact surface and in the sinter paste on the conductor material track, and the contact connection being formed by sintering the sinter paste by means of laser energy.

2. The method according to claim 1, wherein a sinter paste comprising silver or copper nanoparticles is used as the sinter paste.

3. The method according to claim 1, wherein a sinter paste comprising an alcohol solution, a glycol solution or epoxy resin is used as the sinter paste.

4. The method according to claim 1, wherein the sinter paste is applied with a layer thickness of 80 μm to 700 μm.

5. The method according to claim 1, wherein a stranded wire or a wire or a flat wire is used as a contact conductor.

6. The method according to claim 1, wherein laser energy of 10 mJ to 40 mJ is applied for sintering the sinter paste by means of laser energy.

7. The method according to claim 1, wherein a laser is operated with a pulse duration in the range of 1 ms to 4 ms for sintering the sinter paste by means of laser energy.

8. The method according to claim 1, wherein the solvent contained in the sinter paste is at least partially vaporized by heating in an oven.

9. The method according to claim 1, wherein the sinter paste is sintered prior to complete vaporization of the solvent.

10. A chip arrangement comprising a chip, a non-conductive substrate having a conductor material track formed thereon, and a contact conductor, the chip having been arranged on the substrate or on a conductor material track,
wherein
a sinter paste consisting of at least 40% silver or copper has been applied to respective chip contact surfaces of the chip and the conductor material track, the contact conductor having been immersed in the sinter paste on the chip contact surface and in the sinter paste on the conductor material track, a solvent contained in the sinter paste having been vaporized by heating, a contact connection having been formed by sintering the sinter paste by means of laser energy.

11. The chip arrangement according to claim 10,
wherein the substrate is made of silicon or glass or a thermoplastic material.

12. The chip arrangement according to claim 10,
wherein the sinter paste comprises silver or copper nanoparticles.

13. The chip arrangement according to claim 10, wherein the contact conductor is a stranded wire or a wire or a flat wire.

14. The chip arrangement according to claim 10, wherein the contact conductor has a width between 10 μm and 350 μm.

15. The chip arrangement according to claim 10, wherein the sinter paste covers, preferably fully encloses, the section of the contact conductor immersed in the sinter paste.

16. The method according to claim 1, wherein the chip is a power transistor.

17. The method according to claim 1, wherein a flat litz wire, is used as a contact conductor.

18. The method according to claim 1, wherein laser energy of 15 mJ to 30 mJ is applied for sintering the sinter paste.

19. The chip arrangement according to claim 10, wherein the substrate is made of polyethylene naphthalate.

20. The chip arrangement according to claim 10, wherein the sinter paste fully encloses the section of the contact conductor immersed in the sinter paste.
